(19) United States
(12) Patent Application Publication
(10) Pub. No.: US 2024/0422580 A1
(43) Pub. Date: Dec. 19, 2024

(54) ENHANCEMENTS FOR LIGHTWEIGHT EXTENSIBLE REMOTE COMMUNICATIONS SYSTEM DISTRIBUTION MODULE AND METHOD

(71) Applicants: James L. Gilbert, Lenexa, TX (US); Nicholas T. Agnew, Lenexa, TX (US); Auston W. Jacobsen, Lenexa, TX (US)

(72) Inventors: James L. Gilbert, Lenexa, TX (US); Nicholas T. Agnew, Lenexa, TX (US); Auston W. Jacobsen, Lenexa, TX (US)

(21) Appl. No.: 18/670,228

(22) Filed: May 21, 2024

Related U.S. Application Data
(63) Continuation-in-part of application No. 18/257,970, filed on Jun. 16, 2023.

(51) Int. Cl. H04W 24/02; H04W 88/08; H05K 7/14

(52) U.S. Cl. CPC H04W 24/02; H05K 7/1427; H04W 88/08

(57) ABSTRACT

This Continuation-in-Part (CIP) application builds upon a rapidly deployable communication distribution module (DM) designed for robust mesh networking communication in remote, austere locations. The DM features a weatherproof enclosure and utilizes industrial-grade components for reliable operation. It offers multiple connection configurations, including high-performance mesh networking with external antennas, balanced mesh networking with wired backhaul capabilities, and wired connectivity with basic mesh networking potential.

Internal components include a Single-Board Computer (SBC) for central processing, radios for wireless communication and surge-protected, secured wired network connectivity. The DM leverages its radios to automatically establish and maintain a self-healing mesh network, optimizing data flow and network resilience.

### CROSS-REFERENCE TO RELATED APPLICATIONS

This application claims priority to the PCT application titled ‘Remote communications system distribution module and method,’ with U.S. Non-provisional application Ser. No. 18/257,970, which in turn claims priority to the identically titled U.S. Provisional Patent Application No. 63/292,283 filed on Dec. 21, 2021. The entirety of both applications is incorporated herein by reference.

### BACKGROUND

This Continuation-in-Part (CIP) application builds upon the foundation laid in the parent application, focusing specifically on the distribution module (DM) and introduces advancements that extend its functionalities within a multi-station network, particularly in remote and logistically challenging environments.

The original PCT application (claims 1-20) disclosed a foundational communication system utilizing DMs. The present disclosure builds upon this foundation by highlighting advancements in the DM's design and capabilities, with a particular focus on:

Improved Mesh Networking Capabilities: enhancements that strengthen the DM's ability to participate in a robust mesh network with other DMs. These advancements include features such as:

Support for additional meshing protocols or improved routing algorithms for optimized data flow within the network.

The use of multiple radios and antennas for enhanced signal diversity and improved mesh network stability.

Automatic connection and configuration capabilities for seamless integration of new DMs into the network.

Additional Ports and Functionality are incorporated, beyond those present in the parent application claims. It will describe these new ports and the functionalities they enable for the DM, such as:

Support for a wider range of external devices through additional USB or serial ports.

Enhanced wired network connectivity options through additional Ethernet ports.

Advanced data security features through the inclusion of dedicated security ports.

By focusing on these advancements, the present disclosure enhances the DM into a more versatile and powerful component within the multi-station network. The following sections elaborate on the technical details of these improvements-enabling a more resilient, adaptable, and user-friendly communication system in remote environments.

### BRIEF DESCRIPTION OF THE DRAWINGS

FIG. 1 illustrates an external view (bottom) of a Distribution Module (DM) with highlighted ports-showing three possible connection configurations. Configurations vary by the communications methods emphasized and support varying levels of mesh network complexity, according to some embodiments of the present disclosure.

FIG. 2 depicts the interior view of a distribution module (DM), according to some embodiments of the present disclosure, with labeled components. Shown are principal communication, power, heat dissipation, cellular, and network support hardware.

### DETAILED DESCRIPTION OF THE DRAWINGS

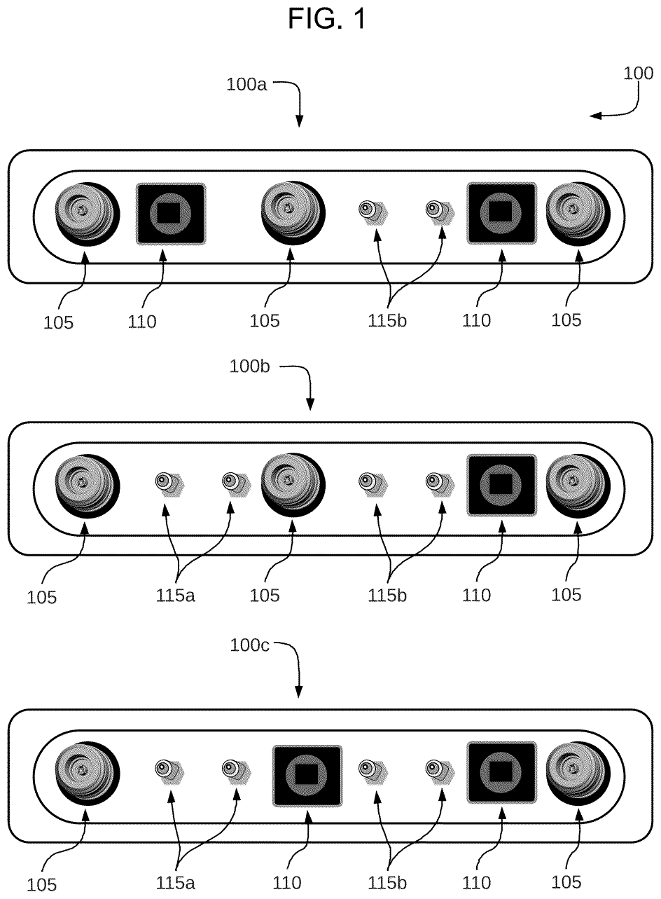

FIG. 1 (100) illustrates the external view (bottom) of the Distribution Module (DM), according to some embodiments of the present disclosure:

Dimensions: The bottom view measures 15.59 inches×3.9 inches.

Material: The DM case is constructed from impact and corrosion-resistant ABS plastic, ensuring durability in harsh environments.

Watertight Design: The DM is designed to be watertight, protecting internal components from moisture ingress.

Temperature Rating: The case has been stress tested to withstand a wide temperature range of −40° F. to 185° F.

Highlighted Ports: Three of multiple possible configurations, according to various embodiments of the present disclosure, shown in FIG. 1, labeled (100a, 100b, 100c). These variations permit customizable functionality, corresponding to varying communication methods or needs and mesh network complexity, according to some embodiments of the present disclosure.

### Connection Configurations:

### (100a): End-of-Line Networking:

This configuration supports remote network communications.

### Key Components:

105: N-type connector: Connects a high-gain external antenna (not shown in FIG. 1) to enhance signal strength and range for the network, as described in the PCT application (Radios 1).

115(b): RP-SMA antenna connectors (reverse polarity): Supports external antenna (not shown in FIG. 1) for network communications.

(100b): High-Performance Mesh Networking (105, 110, 115a, b):

This configuration maximizes mesh network performance.

### Key Components:

105: N-type connector: Connects a high-gain external antenna (not shown in FIG. 1) to enhance signal strength and range for the mesh network, as described in the PCT application (Radios 1 & 2).

115(a, b): RP-SMA antenna connectors (reverse polarity): Supports three external antennas (not shown in FIG. 1) for enhanced signal diversity and improved mesh network stability, aligning with the concept of meshing radios (Radios 1 & 2) in the PCT application.

Balanced Mesh Networking and Wired Connectivity configuration (100c) (105, 110, 115a, b):

This configuration balances mesh networking and wired connectivity options.

### Key Components:

110: ‘push-pull’ style ethernet connector: Allows wired network connection for data transfer and potentially acts as a wired backhaul for the mesh network, as mentioned in the PCT application.

115(a/b): RP-SMA antenna connectors (reverse polarity): Supports two external antennas (not shown in FIG. 1) for improved mesh network performance using Radios 1 & 2 (as described in the PCT).

3. Wired Connectivity with Potential Mesh Networking (110, 115a):
Reconcile Logic of Component Descriptions Per a/b/c Layout

This configuration prioritizes wired connectivity but still retains fundamental mesh networking capabilities.

### Key Components:

110: ‘push-pull’ style ethernet connector: Provides wired network connectivity.

115(a): RP-SMA antenna connector (reverse polarity): Supports a single external antenna (not shown in FIG. 1) for basic mesh networking functionality or serving as a backup for wired connectivity. The PCT application mentions the possibility of using only one radio (Radio 0) in such a scenario.

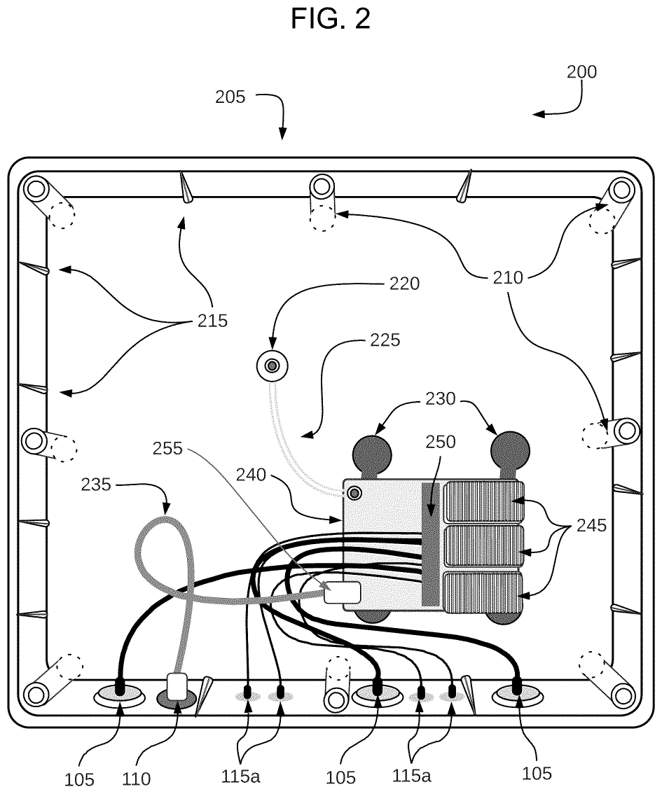

FIG. 2 (200): depicts the internal view of the Distribution Module (DM) with component and connection details. This figure illustrates the internal components of the DM device from a side view. The connections along the bottom correspond to the ones described in FIG. 1.

Enclosure (205): This 205 heavy-duty ABS plastic container is designed for durability and environmental resistance. The specific dimensions (15.43 in×15.59 in×3.9 in) create a calculated fill ratio that optimizes thermal management and protects internal components from harsh environments.

Housing Closure Screw Receptacles (210): These secure the enclosure and allow for easy access to the internal components when needed.

Reinforcement Fins (215): These fins provide additional structural support to the enclosure, particularly important for deployments in rugged environments.

### Grounding System (220, 225):

Grounding Screw (220): This screw allows for attaching the DM to a permanent ground source, if available. This improves electrical safety and signal integrity.

Grounding Wire (225): This wire connects the enclosure's grounding screw (220) to the Single-Board Computer (SBC) (240), ensuring proper grounding throughout the device.

SBC Isolation Mounts (230): These components (230) (two labeled, two obscured) represent the mounting system for the SBC (single-board computer) within the DM device. This system is designed to isolate the SBC from vibrations and shocks, enhancing its durability and performance in harsh environments.

Component (235) represents a CAT5 cable that utilizes Power over Ethernet (PoE) technology. This cable joins the PCL to the DM through connector 110. Both data and power for the DM is delivered through (235) and connects to the SBC (240) through an electrical surge protector (255).

Heat Sinks (245): These dissipate heat generated by the SBC and all radios, maintaining optimal operating temperatures for reliable performance within the mesh network.

Vibration-Isolating Antenna Connectors (250): These connectors provide stable connection points for the omni antenna cables that are attached to the radios. Vibration isolation minimizes signal interference caused by external vibrations, ensuring reliable wireless communication within the mesh network.

Establishing the Mesh: The above DM components work together to establish the mesh network. During initial setup or when a new DM joins the network, the radios will scan for available signals from other DM devices. The Single-Board Computer (SBC) (240) and overwatch software orchestrate this process, using algorithms to identify the strongest and most reliable connections. Once suitable connections are established, the radios will start transmitting and receiving data, forming links within the mesh network.

Maintaining the Mesh: Radios continuously monitor the mesh network's health. They can dynamically adjust transmission power, data routing, and channel selection based on signal strength, network traffic, and potential interference. This ensures efficient data flow and superior network resilience.

The illustrations of embodiments described herein are intended to provide a general understanding of the structure of various embodiments, and they are not intended to serve as a complete description of all the elements and features of apparatus and systems that might make use of the structures described herein. Many other embodiments will be apparent to those of skill in the art upon reviewing the above description. Other embodiments may be utilized and derived therefrom, such that structural and logical substitutions and changes may be made without departing from the scope of this disclosure. Figures are also merely representational and may not be drawn to scale. Certain proportions thereof may be exaggerated, while others may be minimized. Accordingly, the specification and drawings are to be regarded in an illustrative rather than a restrictive sense. Thus, although specific embodiments have been illustrated and described herein, it should be appreciated that any arrangement calculated to achieve the same purpose may be substituted for the specific embodiments shown. This disclosure is intended to cover any and all adaptations or variations of various embodiments. Combinations of the above embodiments, and other embodiments not specifically described herein, will be apparent to those of skill in the art upon reviewing the above description. Therefore, it is intended that the disclosure not be limited to the particular embodiment(s) disclosed.

What is claimed is:

1. A distribution module (DM) device comprising:
A rigid case having a hollow interior;
A single-board computer (SBC) mounted within the rigid case;
A first radio configured to serve as an internet access point and communicably coupled within the rigid case to the SBC; and
At least one other radio with meshing capabilities and communicably coupled within the rigid case to the SBC, wherein:
The SBC and at least one of the radios (including the first radio or one of the meshing radios) are configured to communicate using a configurable access frequency.
This configurable access frequency is selectable within a designated bandwidth range.

2. The distribution module (DM) device of claim 1, wherein:
The designated bandwidth range for the configurable access frequency encompasses at least one of:
A 900 MHz bandwidth.
A 2.4 GHz bandwidth.
A 5 GHz bandwidth.
A 6 GHz bandwidth.

3. The distribution module (DM) device of claim 1, wherein:
The configurable access frequency allows for user-selectable adjustments based on network needs and environmental factors.

4. The distribution module (DM) device of claim 1, further comprising:
Two or more DM devices, each DM device comprising the elements of claim 1, and further comprising:
A single-board computer (SBC).
At least one radio with meshing capabilities.
A computing device communicably coupled with the two or more DM devices, wherein the computing device has an overwatch software program operating thereon; and
The overwatch software program is configured for:
Remote monitoring and configuration of the DM devices.
Real-time network health reporting and diagnostics for the DM devices.
Over-the-air software updates for the DM devices, including firmware and security updates.
User management for access control to the DM devices.

5. The distribution module (DM) device of claim 1, wherein:
A plurality of ports extending through the rigid case and at least one of electrically and communicatively coupled with one or more of the SBC, the first radio, the second radio, and the third radio.
A plurality of external antennae, each coupled with vibration-isolating connectors, to at least one of the plurality of ports.

6. The distribution module (DM) device of claim 1, wherein:
A plurality of ports extending through the rigid case, wherein at least one of the ports is configurable to receive power from a variety of sources including Power over Ethernet (PoE) and alternative power supply options suitable for remote environments.

7. A distribution module (DM) device comprising:
A rigid case having a hollow interior;
A single-board computer (SBC) mounted within the rigid case;
A first radio configured to serve as an internet access point and communicably coupled within the rigid case to the SBC;
A second radio with meshing capabilities and communicably coupled within the rigid case to the SBC;
A third radio with meshing capabilities and communicably coupled within the rigid case to the SBC, wherein each radio is configured to operate within a designated bandwidth range.

8. The rigid case of claim 1, wherein the hollow interior is further configured to provide thermal isolation for the internal components, enabling operation within an improved temperature range of −40° F. to 185° F., particularly suitable for extreme environments.

9. The distribution module (DM) device of claim 1, further comprising:
A single-board computer (SBC) mounted within the rigid case; and
At least one vibration and shock-isolating mounting element, wherein the SBC is secured to the rigid case using the at least one vibration and shock-isolating mounting element.
The at least one vibration and shock-isolating mounting element comprises one or more of the following:
Elastomeric isolators: These are elastic polymer components that absorb and dampen vibrations.
Spring isolators: These utilize metal springs to isolate vibrations by providing a flexible connection between the SBC and the rigid case.
Viscoelastic dampers: These combine elastomeric materials with viscous fluids to achieve broader frequency range isolation and additional damping capabilities.
